(19) United States
(12) Patent Application Publication
(10) Pub. No.: US 2026/0068545 A1
(43) Pub. Date: Mar. 5, 2026

(54) MEMRISTOR DEVICES FOR NEUROMORPHIC COMPUTING

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/817,141

(22) Filed: Aug. 27, 2024

(51) Int. Cl. H10N 70/00; H10B 63/00; H10N 70/20

(52) U.S. Cl. CPC H10N 70/8418; H10B 63/00; H10N 70/011; H10N 70/24; H10N 70/8833

(57) ABSTRACT

The present disclosure relates to memristor devices for neuromorphic computing. A memristor device may include a first electrode, an oxide layer, an interface layer fabricated on the oxide layer, and a second electrode fabricated on the interface layer. The first electrode may include a noble metal and/or an inert metal, such as platinum, palladium, iridium, tungsten, molybdenum, ruthenium, etc. The oxide layer may include a dielectric oxide, such as silicon dioxide, hafnium dioxide, tantalum pentoxide, etc. The interface layer may include a discontinuous layer of a dielectric material, such as Al₂O₃, Y₂O₃, MgO, etc. The second electrode may include one or more metallic materials that may provide metal ions in response to the application of a suitable voltage to the memristor device, such as copper, silver, etc. In some embodiments, the memristor device may further include an interface layer positioned between the first electrode and the oxide layer.

### TECHNICAL FIELD

The implementations of the disclosure relate generally to memristor devices and, more specifically, to memristor devices for neuromorphic computing and methods for fabricating the same.

### BACKGROUND

Memristor devices may be used to implement a neural network that emulates synaptic transmission and neuronal functions. Non-volatile memristors maintain their conductance state over time without power, making them ideal for storing weights in the neurons of a neural network. These memristors utilize a filament or local conductive channel enriched with oxygen vacancies, the conductance of which can be precisely tuned and retained through the control of oxygen ion migration. Volatile memristors, on the other hand, exhibit temporary high conductance states that decay over time when the stimulating electric field is removed. This characteristic is due to the migration of metallic ions within the memristor. Volatile memristors may be used to simulate synapses in neuromorphic computing, allowing for transient connections between neurons that mimic the natural communication via neurotransmitters in the brain.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a semiconductor device including a memristor device is provided. The memristor device includes a first electrode; an oxide layer fabricated on the first electrode; a second electrode fabricated on the oxide layer; and a first interface layer fabricated between the oxide layer and the second electrode. The oxide layer includes at least one dielectric oxide. The first interface layer includes a layer of a first dielectric material.

In some embodiments, the first electrode includes at least one of platinum (Pt), palladium (Pd), iridium (Ir), tungsten (W), molybdenum (Mo), or ruthenium (Ru).

In some embodiments, the dielectric oxide includes at least one of silicon dioxide (SiO₂), hafnium dioxide (HfO₂), or tantalum pentoxide (Ta₂O₅).

In some embodiments, the first dielectric material includes at least one of Al₂O₃, Y₂O₃, or MgO.

In some embodiments, the second electrode includes at least one of Cu or Ag.

In some embodiments, the first interface layer includes a discontinuous layer of the first dielectric material, wherein at least a portion of the second electrode is deposited on the oxide layer through the discontinuous layer of the first dielectric material.

In some embodiments, the semiconductor device further includes a capping layer fabricated on the second electrode, wherein the capping layer includes a metal or metal nitride.

In some embodiments, the semiconductor device further includes a layer of tantalum deposited between the first electrode and a substrate.

In some embodiments, the memristor device includes a second interface layer fabricated between the first electrode and the oxide layer, wherein the second interface layer includes a second dielectric material.

In some embodiments, the second dielectric material includes at least one of Al₂O₃, Y₂O₃, or MgO, and wherein the second interface layer includes a discontinuous layer of the second dielectric material. At least a portion of the oxide layer including the dielectric oxide is deposited on the first electrode through the second interface layer.

According to one or more aspects of the present disclosure, a method for fabricating a memristor device is provided. The method includes fabricating, on a first electrode, an oxide layer including at least one dielectric oxide; fabricating, on the oxide layer, an interface layer including a first dielectric material; and fabricating a second electrode on the interface layer and the oxide layer.

In some embodiments, the first electrode includes at least one of platinum (Pt), palladium (Pd), iridium (Ir), tungsten (W), molybdenum (Mo), or ruthenium (Ru).

In some embodiments, the dielectric oxide includes at least one of silicon dioxide (SiO₂), hafnium dioxide (HfO₂), or tantalum pentoxide (Ta₂O₅).

In some embodiments, the first dielectric material includes at least one of Al₂O₃, Y₂O₃, or MgO.

In some embodiments, the second electrode includes a metallic material for providing metal ions during drift switching of the memristor device, wherein the metallic material includes at least one copper (Cu) or silver (Ag).

In some embodiments, the first interface layer includes a discontinuous layer of the first dielectric material, and wherein fabricating the second electrode includes depositing at least a portion of the metallic material on the oxide layer through the discontinuous layer of the first dielectric material.

In some embodiments, the method further includes fabricating a capping layer on the second electrode, wherein the capping layer includes at least one of a metal or a metal nitride.

In some embodiments, the method further includes depositing a layer of tantalum metal on a substrate, wherein the first electrode is fabricated on the layer of tantalum.

In some embodiments, the method further includes fabricating, on the first electrode a second interface layer including a second dielectric material, wherein the oxide layer is fabricated on the second interface layer.

In some embodiments, the second dielectric material includes at least one of Al₂O₃, Y₂O₃, or MgO, and wherein the second interface layer includes a discontinuous layer of the second dielectric material, and wherein at least a portion of the oxide layer including the dielectric oxide is deposited on the first electrode through the second interface layer.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIGS. 1A, 1B, 1C, 1D, 1E, 1F, 1G, 1H, and 1I illustrate cross-sectional views of structures for fabricating semiconductor devices comprising memristor devices in accordance with one implementation of the present disclosure.

FIGS. 2A, 2B, 2C, 2D, 2E and 2F illustrate structures for fabricating semiconductor devices comprising memristor devices in accordance with another implementation of the present disclosure.

FIGS. 3A, 3B, and 3C are diagrams illustrating cross-sectional views of structures for fabricating semiconductor devices comprising memristor devices in accordance with a further implementation of the present disclosure.

FIGS. 4, 5, and 6 are flow diagrams illustrating example processes for fabricating memristor devices in accordance with some embodiments of the present disclosure.

### DETAILED DESCRIPTION

Aspects of the disclosure provide memristor devices and methods for fabricating the memristor devices.

Memristor devices may be used to implement a neural network that emulates synaptic transmission and neuronal functions. Non-volatile memristors maintain their conductance state over time without power, making them ideal for storing weights in the neurons of a neural network. Volatile memristors, on the other hand, exhibit temporary high conductance states that decay over time or when the stimulating electric field is removed. This characteristic is attributed to the migration of metallic ions within the memristor. In particular, such volatile memristors may exhibit synaptic switching behaviors that may involve "on" and "off" switching mechanisms under varying conditions. "On" switching (or drift switching) occurs in the presence of an electric field and involves the formation or strengthening of a conductive path through drifting mechanisms, where electrically driven filament formation occurs. "Off" switching (or diffusive switching), which occurs without an electric field, involves the decay, rupture, or dissolution of this conductive path through diffusive mechanisms, influenced by factors such as chemical gradients, surface tension, etc. The synaptic switching behaviors may be utilized to implement synapses in a neural network.

However, it may be challenging to implement synapses using existing memristor devices due to significant variations in diffusive switching, which may be rooted in inconsistencies in the drift-switching behaviors of these devices. These variations lead to unpredictability in both "On" switching (set voltages) and "Off" switching (decay times), which hinders the reliable emulation of synaptic behavior.

Accordingly, the present disclosure provides volatile memristor devices with consistent synaptic switching behaviors that are suitable for implementing neuromorphic computing applications. In some embodiments, a memristor device may include a first electrode, an oxide layer fabricated on the first electrode, an interface layer fabricated on the oxide layer, and a second electrode fabricated on the interface layer. The first electrode may include a noble metal and/or an inert metal, such as platinum (Pt), palladium (Pd), iridium (Ir), tungsten (W), molybdenum (Mo), ruthenium (Ru), etc. The oxide layer may include a dielectric oxide, such as silicon dioxide (SiO₂), hafnium dioxide (HfO₂), tantalum pentoxide (Ta₂O₅), etc. The interface layer may include a discontinuous layer of a dielectric material that is more chemically stable than the dielectric oxide, such as aluminum oxide (Al₂O₃), yttrium oxide (Y₂O₃), etc. The second electrode may include one or more metallic materials that may provide metal ions in response to the application of a suitable voltage to the memristor device. In some embodiments, the second electrode may include copper (Cu), silver (Ag), etc. In some embodiments, the memristor device may further include an additional interface layer positioned between the first electrode and the oxide layer. In some embodiments, the memristor device may further include one or more capping layers to prevent the migration of the metal ions outside of the memristor device.

When a voltage is applied to the memristor device, metal ions (e.g., Cu ions, Ag ions, etc.) may drift from the second electrode through the oxide layer to the first electrode, forming a conductive path or filament. This process may also be referred to as “drift switching.” Due to the presence of the interface layer(s), drift switching may occur at specific locations where the second electrode is in direct contact with the oxide layer. This may focus the electric field to the limited specific locations, reduce randomness in the drift switching, and minimize variations in filament location, size, or shape. As a result, cycle-to-cycle variations in the switching behaviors of the memristor devices may be reduced, leading to more consistent synaptic switching behaviors.

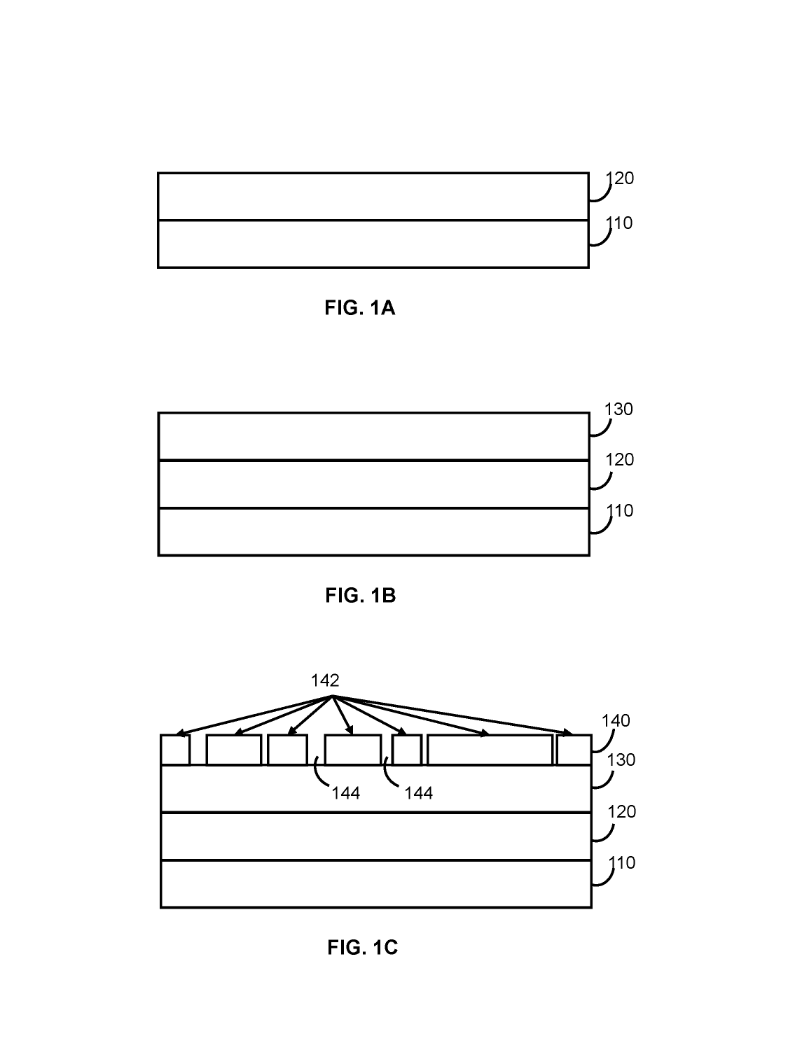

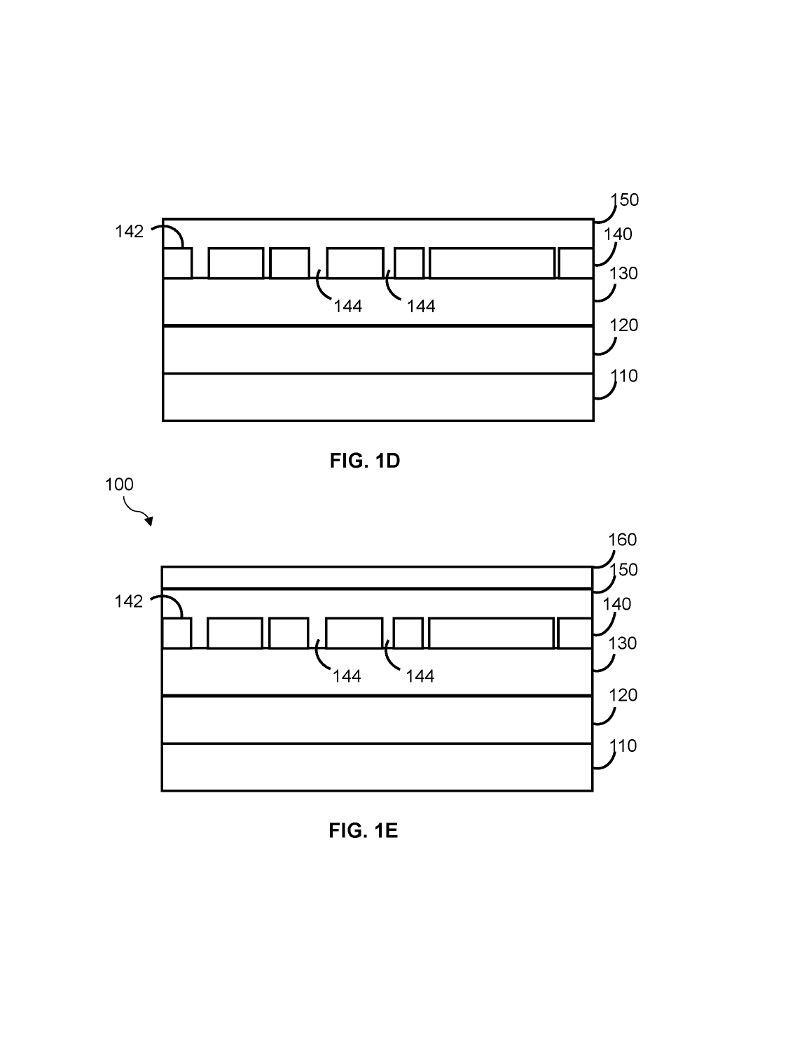

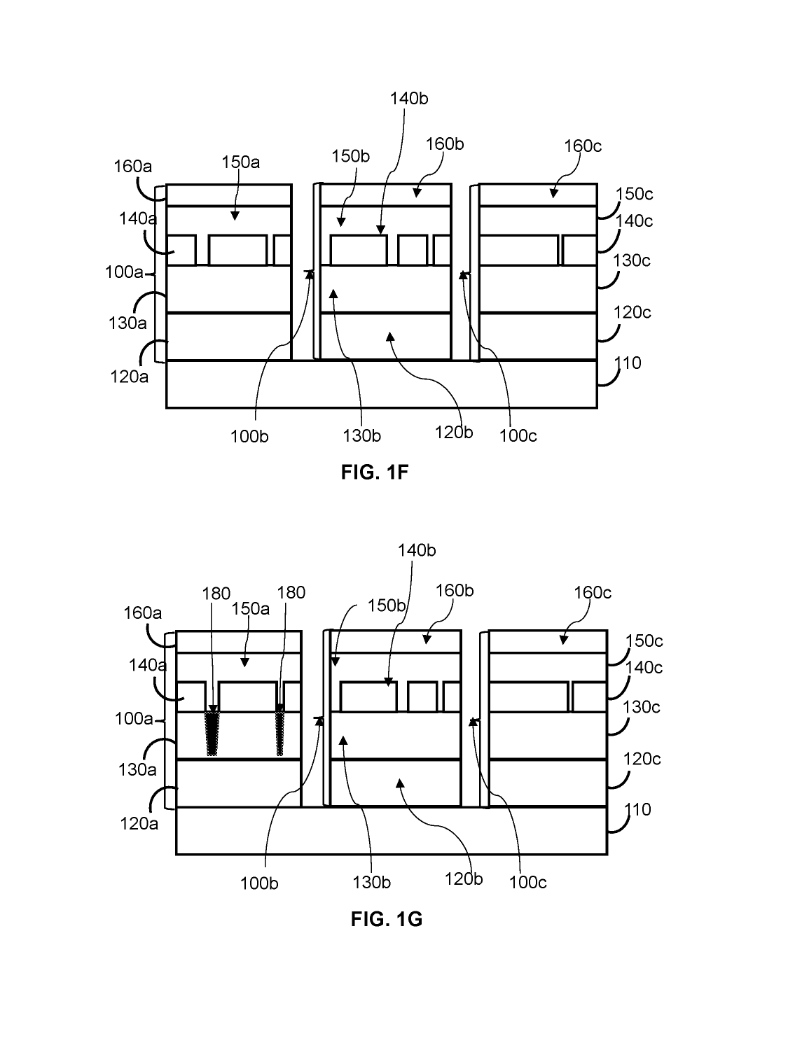

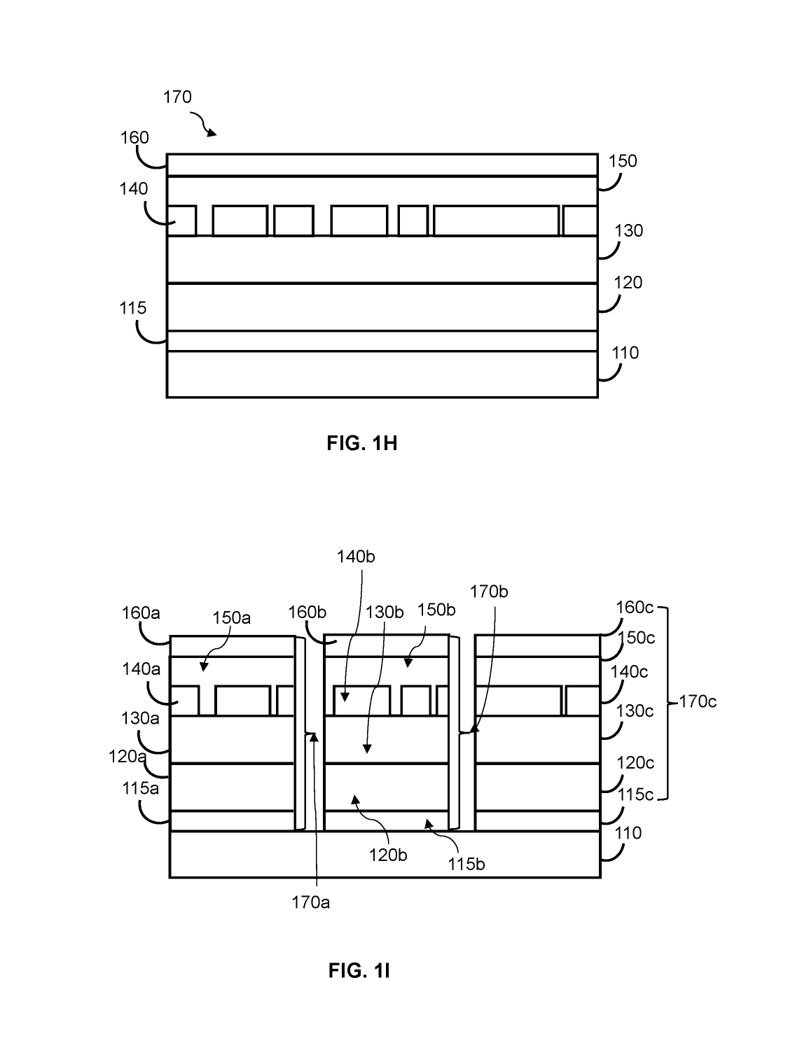

FIGS. 1A, 1B, 1C, 1D, 1E, 1F, 1G, 1H, and 1I illustrate cross-sectional views of structures for fabricating semiconductor devices comprising memristor devices in accordance with one implementation of the present disclosure.

As shown in FIG. 1A, a substrate 110 may be provided. A first electrode 120 may be fabricated on the substrate 110. The substrate 110 may include one or more layers of any suitable material that may serve as a substrate for an RRAM device, such as silicon (Si), silicon dioxide (SiO₂), silicon nitride (Si₃N₄), aluminum oxide (Al₂O₃), aluminum nitride (AlN), etc. In some embodiments, the substrate 110 may include diodes, transistors, interconnects, integrated circuits, one or more other RRAM devices, etc. In some embodiments, the substrate 110 may include a driving circuit including one or more electrical circuits (e.g., an array of electrical circuits) that may be individually controllable. In some embodiments, the driving circuit may include one or more complementary metal-oxide-semiconductor (CMOS) drivers.

The first electrode 120 may include any suitable material that is electronically conductive and non-reactive to the oxide layer to be fabricated on the first electrode 120 (also referred to as the “non-reactive” material). As an example, the first electrode 120 may include a noble metal and/or an inert metal, such as platinum (Pt), palladium (Pd), iridium (Ir), tungsten (W), molybdenum (Mo), ruthenium (Ru), etc. The first electrode 120 may also be referred to as the “non-reactive electrode.”

Referring to FIG. 1B, an oxide layer 130 of one or more dielectric oxides may be fabricated on the first electrode 120. The dielectric oxide may be a base oxide, such as silicon dioxide (SiO₂), hafnium dioxide (HfO₂), tantalum pentoxide (Ta₂O₅), etc. In some embodiments, the chemical stability of the non-reactive material in the first electrode 120 may be higher than that of the dielectric oxide(s) in oxide layer 130. Unlike certain non-volatile resistive random-access memory (RRAM) that may include oxygen deficiencies intentionally introduced during the fabrication process, the memristor devices described herein include dielectric oxide(s) that are in stoichiometry or close to stoichiometry.

As shown in FIG. 1C, an interface layer 140 may be fabricated on the oxide layer 130. The interface layer 140 may be a dielectric material (also referred to as the “first dielectric material”) that is more chemically stable than the dielectric oxide in the oxide layer and the electrode materials in the electrodes of the memristor device to be fabricated. As a result, the dielectric material will not react with the dielectric oxide or the electrode materials. Examples of the first dielectric material include Al₂O₃, Y₂O₃, MgO, etc.

As shown, the interface layer 140 may include a discontinuous film 142 of the dielectric material (e.g., islands of the dielectric material) with pores and/or pin-holes 144. The pores and/or pin-holes 144 may be randomly dispersed in the interface layer 140. While a certain number of pores are illustrated in FIG. 1C, this is merely illustrative. The interface layer 140 may include any suitable number of pores and/or pin-holes. In some embodiments, a thickness of the interface layer 140 and/or the discontinuous film 142 may be between about 0.2 nm and about 0.5 nm. In some embodiments, the discontinuous film 142 may be an Al₂O₃ film having a thickness equal to or less than 0.5nm. In some embodiments, the discontinuous film 142 may be and/or include an Al₂O₃ film having a thickness of less than 1 nm.

As referred to herein, a layer may be regarded as being a discontinuous layer if the layer covers some, but not all, portions of the layer underneath. The discontinuous film 142 of the dielectric material may be fabricated by depositing the dielectric material to a suitable thickness, i.e., a layer that is not thick enough to form a continuous layer of the dielectric layer. In some embodiments, the thickness of the interface layer and/or the discontinuous film of the dielectric material may be approximately on the order of magnitude of the diameter of a single atom or molecule of the dielectric material. In some embodiments, a thickness of the interface layer 140 may be between about 0.2 nm and about 0.5 nm. In some embodiments, a thickness of the interface layer 140 may be about 0.3 nm. As a more particular example, the thickness of an Al₂O₃ monolayer is estimated to be more than the diameter of an Al ion plus the diameter of an oxygen ion, where the diameter of an oxygen ion is 0.252nm; the diameter of an Al³⁺ ionic is 0.136nm; and the size of an AlO ion pair is 0.388nm. As such, an Al₂O₃ layer may be discontinuous when the thickness of the Al₂O₃ film is less than about 0.4 nm. As another more particular example, the diameter of a Si⁴⁺ ion is 0.108nm; the size of an Si-O ionic pair is 0.360 nm. Thus, a complete SiO₂ monolayer is often not formed, if the thickness of a deposited SiO₂ layer is less than 0.4 nm. In some embodiments, even when the thickness of a deposited film is thicker than 0.4 nm, a dielectric film may still be non-continuous due to the surface energy (or wettability) between the dielectric film and the first electrode.

Referring to FIG. 1D, a second electrode 150 may be fabricated on the interface layer 140. The second electrode 150 may include any suitable material that is electronically conductive and may function as a source of metal ions during drift switching of the memristor devices to be fabricated. For example, the metallic material in the second electrode 150 may include Cu, Ag, etc. The second electrode 150 may also be referred to herein as an active electrode. The metallic material may be deposited on the top surface of the discontinuous film of the dielectric material and the top surface of the oxide layer 130. One or more portions of the second electrode 150 may be deposited on the discontinuous film 142 of the dielectric material and one or more portions of the second electrode 150 may be deposited on the oxide layer 130 through the pores and/or pin-holes 144. As such, at least a portion of the second electrode 150 may be in direct contact with the oxide layer 130 through the interface layer 140 (e.g., through the pores and/or pin-holes 144).

In some embodiments, as shown in FIG. 1E, a capping layer 160 may be fabricated on the second electrode 150 to form a device stack 100. The capping layer 160 may include any suitable metallic material that may limit the migration of metal ions from the second electrode 150 to components outside the memristor device. In some embodiments, the capping metal layer 160 may include tantalum (Ta), tantalum nitride (TaN), tungsten (W), tungsten nitride (WN), etc.

In some embodiments, non-volatile resistive random-access memory (RRAM) (not shown) may be fabricated beneath the first electrode 120 and/or above the second electrode 150 for implementing a neuron network.

Referring to FIG. 1F, the device stack 100 may be patterned and etched to fabricate a plurality of memristor devices 100a, 100b, . . ., 100c. The etching of the first electrode 120 may form first electrodes 120a, 120b, . . ., 120c. The etching of the oxide layer 130 may fabricate oxide layers 130a, 130b, . . . 103c. The etching of the interface layer may fabricate interface layers 140a, 140b, . . ., 140c. The etching of the second electrode 150 may fabricate second electrodes 150a, 150b, . . ., 150c. The etching of the capping layer 160 may fabricate capping layers 160a, 160b, . . ., 160c. Each of the memristor devices 100a, 100b, . . ., 100c, may include a first electrode (first electrodes 120a, 120b, . . ., 120c), an oxide layer (oxide layers 130a, 130b, . . ., 130c), a second electrode (second electrodes 150a, 150b, . . ., 150c), and an interface layer (interface layers 140a, 140b, . . ., 140c) positioned between the oxide layer and the second electrode. Each of the memristor devices 100a, 100b, . . ., 100c may further include a capping layer (capping layers 160a, 160b, . . ., 160c).

When a suitable voltage is applied to a memristor device 100a, metal ions in the second electrode 150a may drift from the second electrode 150a through the oxide layer 130a towards the first electrode 120a, forming one or more conductive paths or filaments 180, as shown in FIG. 1G. This process may also be referred to as “drift switching.” Due to the presence of the interface layer 140, the drift switching may occur at specific locations where the second electrode 150a is in direct contact with the oxide layer 130a. The incorporation of the interface layer may thus focus the electric field to specific locations within the device, reduce randomness in the drift switching, and minimize variations in filament location, size, or shape. As a result, cycle-to-cycle switch variations may be reduced, leading to more consistent synaptic switching.

Referring to FIG. 1H, a layer 115 of tantalum (Ta) metal may be fabricated between the first electrode 120 and the substrate 110 in some embodiments. A device stack 170 as shown in FIG. 1H may include the layer 115 of Ta metal, the first electrode 120, the oxide layer 130, the interface layer 140, the second electrode 150, and the capping layer 160. Layer 115 may function as an adhesion layer as well as a capping layer to prevent active metal ions (e.g., Cu ions, Ag ions, etc.) from migrating outside the memristor device.

Referring to FIG. 1I, the device stack 170 may be patterned and etched to fabricate a plurality of memristor devices 170a, 170b, . . ., 170c. Each of the memristor devices may include a layer of Ta metal (e.g., layer 115a, 115b, . . ., 115c), a first electrode (e.g., electrode 120a, 120b, . . ., 120c), an oxide layer (e.g., oxide layer 130a, 130b, . . ., 130c), an interface layer (e.g., interface layers 140a, 140b, . . ., 140c), a second electrode (e.g., electrode 150a, 150b, . . ., 150c), and/or a capping layer (e.g., capping layer 160a, 160b, . . ., 160c).

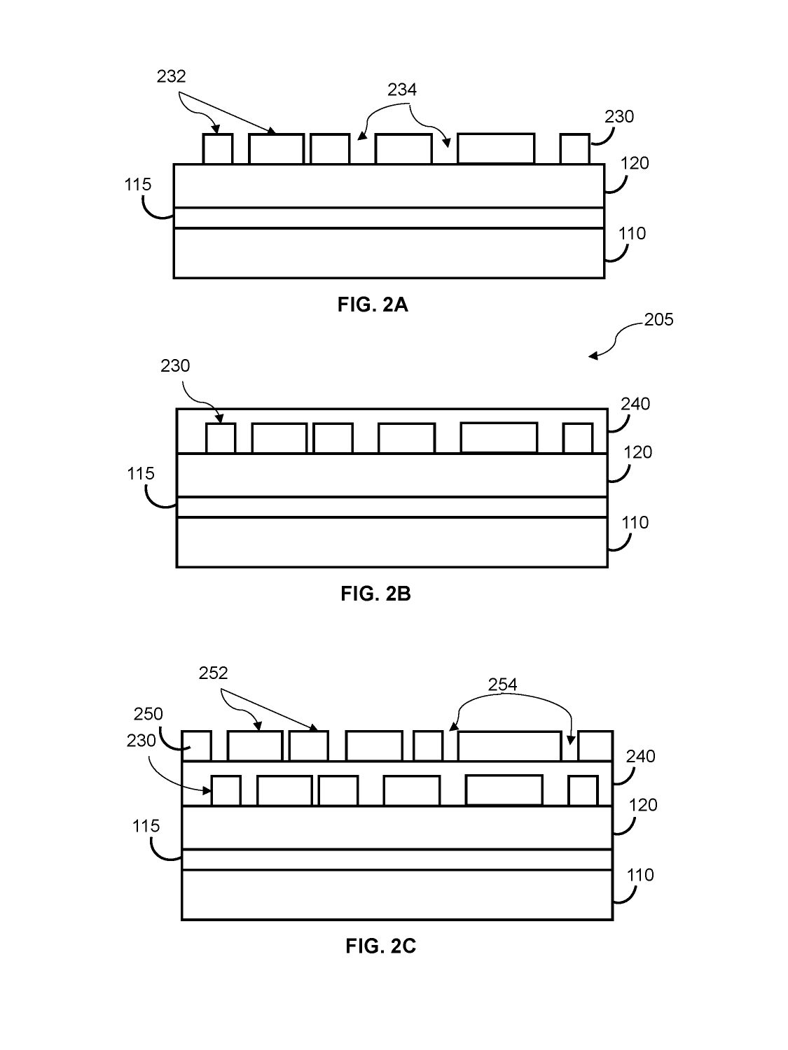

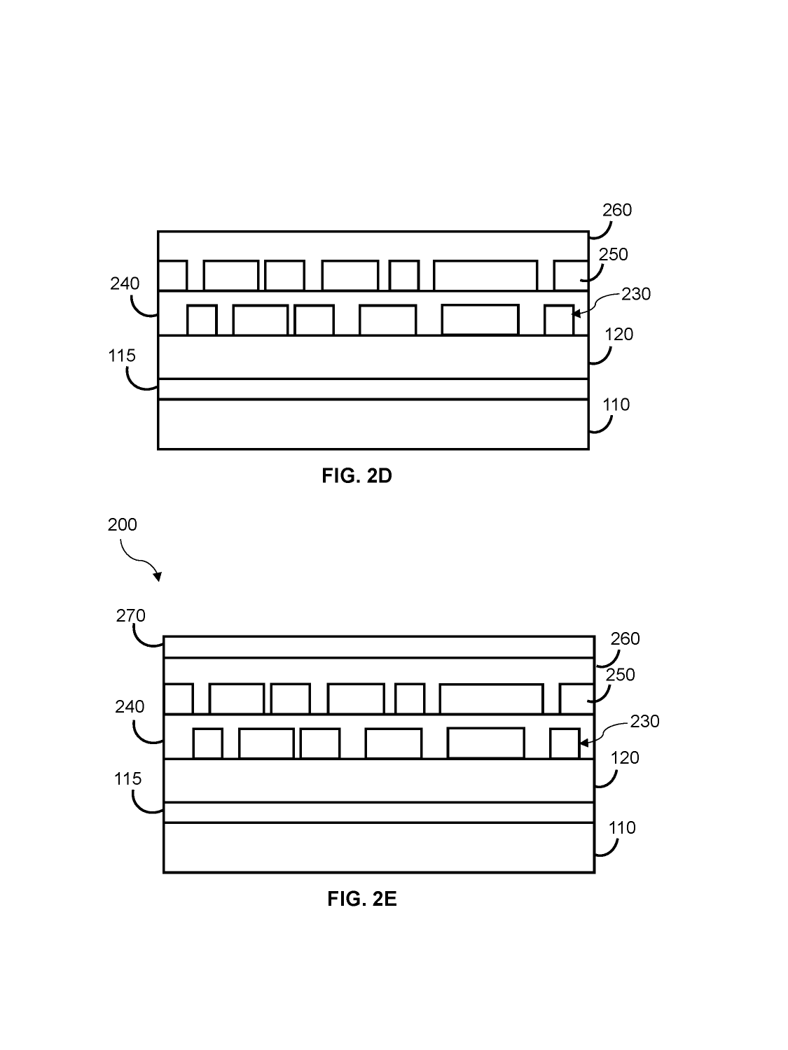

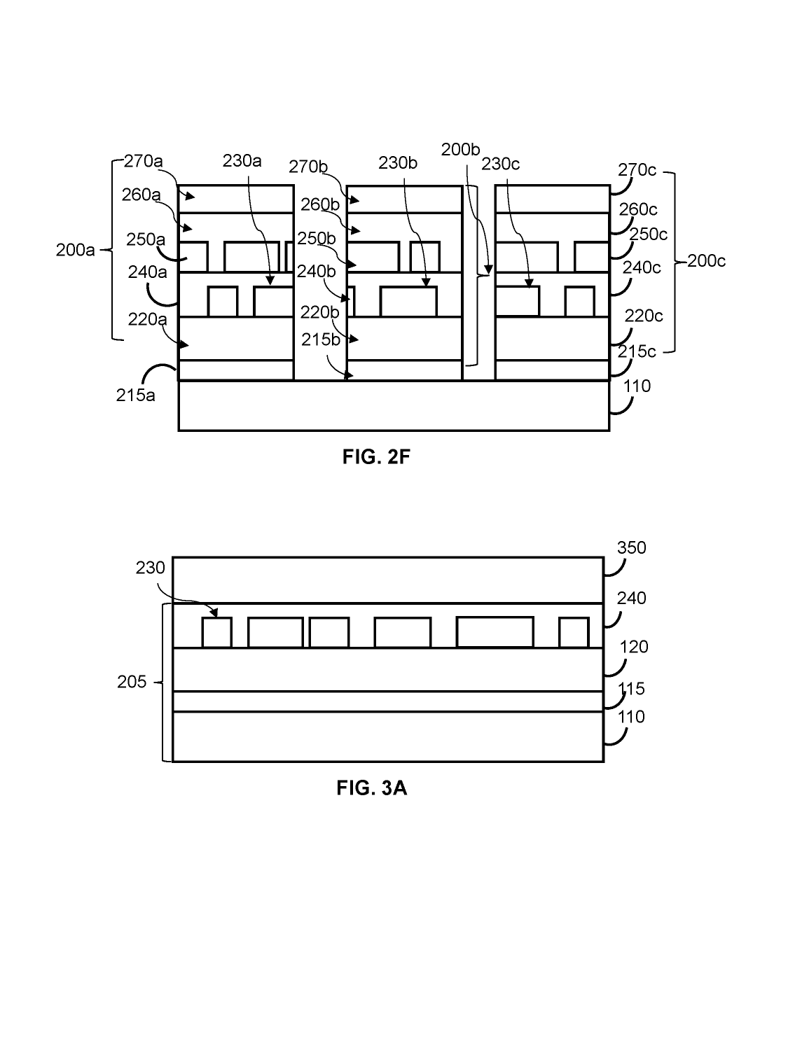

FIGS. 2A, 2B, 2C, 2D, 2Eand 2F illustrate structures for fabricating semiconductor devices comprising memristor devices with multiple interface layers in accordance with some embodiments of the present disclosure.

As illustrated in FIG. 2A, an interface layer 230 (also referred to as the “interface layer ILA”) may be fabricated on the first electrode 120. In some embodiments, the interface layer 230 may include a discontinuous film 232 of a dielectric material (also referred to as the “second dielectric material”) with pores and/or pin-holes 234. The second dielectric material may be more chemically stable than the dielectric oxide in the oxide layer to be fabricated on the interface layer 230. As an example, the second dielectric material may include Al₂O_{3,} MgO, Y₂O₃, etc.

As shown, the interface layer ILA may include a discontinuous film 232 of the second dielectric material (e.g., islands of the second dielectric material) with one or more pores and/or pin-holes 234 (also referred to as the “one or more second pores and/or pin-holes”). The pore(s) 234 may have any suitable size and/or dimension. Multiple pores 234 may or may not have the same size and/or dimension. The pores and/or pin-holes 234 may be dispersed randomly in the interface layer 230.

In some embodiments, a thickness of the interface layer 230 and/or the second discontinuous film (also referred to as the “second thickness”) may be between about 0.2 nm and about 0.5 nm. As another example, the interface layer 230 may include a discontinuous Al₂O₃ film having a thickness equal to or less than 0.5 nm. In some embodiments, the second interface layer 230 may include a discontinuous Al₂O₃ film having a thickness less than 1 nm.

As shown in FIG. 2B, an oxide layer 240 may be fabricated on the interface layer 230 and the first electrode 120. The oxide layer 240 may include one or more dielectric oxides, such as silicon dioxide (SiO₂), hafnium dioxide (HfO₂), tantalum pentoxide (Ta₂O₅), etc. The dielectric oxide may be a base oxide in stoichiometry or close to stoichiometry. In some embodiments, the chemical stability of the interface layer ILA is higher than that of the non-reactive material in the first electrode 120 and that of the dielectric oxide(s) in the oxide layer 240. One or portions of the oxide layer 240 may be fabricated on the discontinuous film of the second dielectric material. At least a portion of the oxide layer 240 may be directly deposited on the first electrode 120 through the interface layer 230 (e.g., through the pores and/or pin-holes 234).

As shown in FIG. 2C, an interface layer 250 (also referred to as the “interface layer ILB”) may be fabricated on the oxide layer 240. The interface layer 250 may include a discontinuous film 252 of a dielectric material (the first dielectric material) with pores and/or pin-holes 254. The dielectric material of the interface layer ILB may be more chemically stable than the dielectric oxide in the oxide layer 240 and the electrode materials in the electrodes of the memristor devices to be fabricated. As a result, the first dielectric material will not react with the dielectric oxide or the electrode materials. Examples of the dielectric material include Al₂O₃, Y₂O₃, MgO, etc.

As shown in FIG. 2D, a second electrode 260 may be fabricated on the oxide layer 240 and the interface layer 250. The second electrode 260 may include any suitable material that is electronically conductive and may function as a source of metal ions during drift switching of the memristor devices to be fabricated. For example, the metallic material in the second electrode 260 may include Cu, Ag, etc. The second electrode 260 may also be referred to herein as an active electrode.

As shown in FIG. 2E, a capping layer 270 may be fabricated on the second electrode 260 to form a device stack 200. The capping layer 270 may include any suitable metallic material that may limit the migration of metal ions outside the memristor device. In some embodiments, the capping layer 270 may include Ta metal, TaN, W, WN, etc.

Referring to FIG. 2F, the device stack 200 may be patterned and etched to fabricate a plurality of memristor devices 200a, 200b, . . ., 200c. The etching of the layer 115 may form layers 215a, 215b, . . ., 215c of Ta metal. The etching of the first electrode 120 may form first electrodes 220a, 220b, . . ., 220c. The etching of the interface layer 230 may fabricate interface layers 230a, 230b, . . ., 230c. The etching of the oxide layer 240 may fabricate oxide layers 240a, 240b, . . . 240c. The etching of the interface layer 250 may fabricate interface layers ILB 250a, 250b, . . ., 250c. The etching of the second electrode 260 may fabricate second electrodes 260a, 260b, . . ., 260c. The etching of the capping layer 270 may fabricate capping layers 270a, 270b, . . ., 270c. Each of the memristor devices 200a, 200b, . . ., 200c, may include a layer of Ta metal (layer 215a, 215b, . . ., 215c), a first electrode (first electrodes 220a, 220b, . . ., 220c), an oxide layer (oxide layers 240a, 240b, . . ., 240c), a second electrode (second electrodes 260a, 260b, . . ., 260c), an interface layer ILA (interface layers 230a, 230b, . . ., 230c) positioned between the first electrode and the oxide layer, and an interface layer (interface layers 250a, 250b, . . ., 250c) positioned between the oxide layer and the second electrode. Each of the memristor devices 200a, 200b, . . ., 200c may further include a capping layer (capping layers 270a, 270b, . . ., 270c).

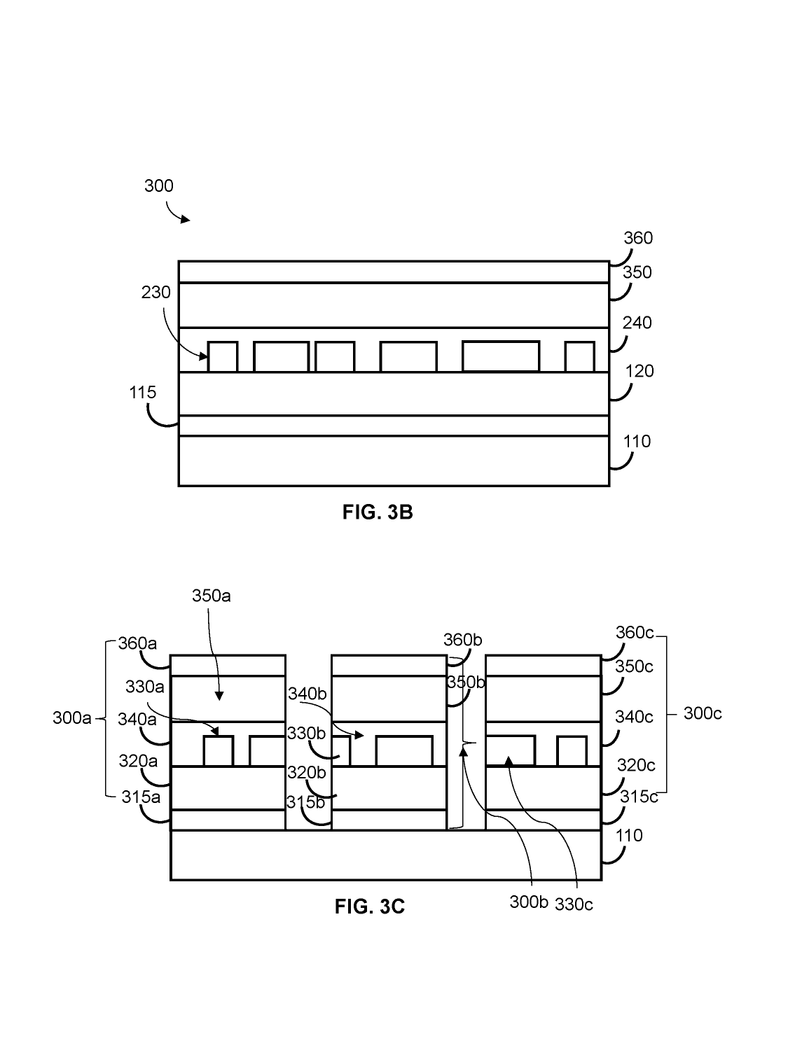

FIGS. 3A, 3B, and 3C are diagrams illustrating cross-sectional views of structures for fabricating semiconductor devices comprising memristor devices in accordance with another implementation of the present disclosure.

As shown in FIG. 3A, a second electrode 350 may be fabricated on the device stack 205 as depicted in FIG. 2B. In particular, the second electrode 350 may be fabricated on the oxide layer 240. The second electrode 350 may include any suitable material that is electronically conductive and may function as a source of metal ions during drift switching in the memristor devices to be fabricated. For example, the metallic material in the second electrode 350 may include Cu, Ag, etc. The second electrode 350 may also be referred to herein as an active electrode.

As shown in FIG. 3B, a capping layer 360 may be fabricated on the second electrode 350 to form a device stack 300. The capping layer 360 and the capping layer 270 in FIG. 2E may include the same similar materials and may perform the same or substantially the same functions.

As shown in FIG. 3C, the device stack 300 may be patterned and etched to fabricate a plurality of memristor devices 300a, 300b, . . ., 300c. Each of the memristor devices 300a, 300b, . . . 300c may include a layer of Ta metal (e.g., layer 315a, 315b, . . ., 315c), a first electrode (e.g., electrode 320a, 320b, . . ., 320c), an oxide layer (e.g., oxide layer 340a, 340b, . . ., 340c), a second electrode (e.g., electrode 350a, 350b, . . ., 350c), an interface layer (e.g., interface layers 330a, 330b, . . ., 330c) positioned between the oxide layer and the first electrode, and/or a capping layer (e.g., capping layer 360a, 360b, . . ., 360c).

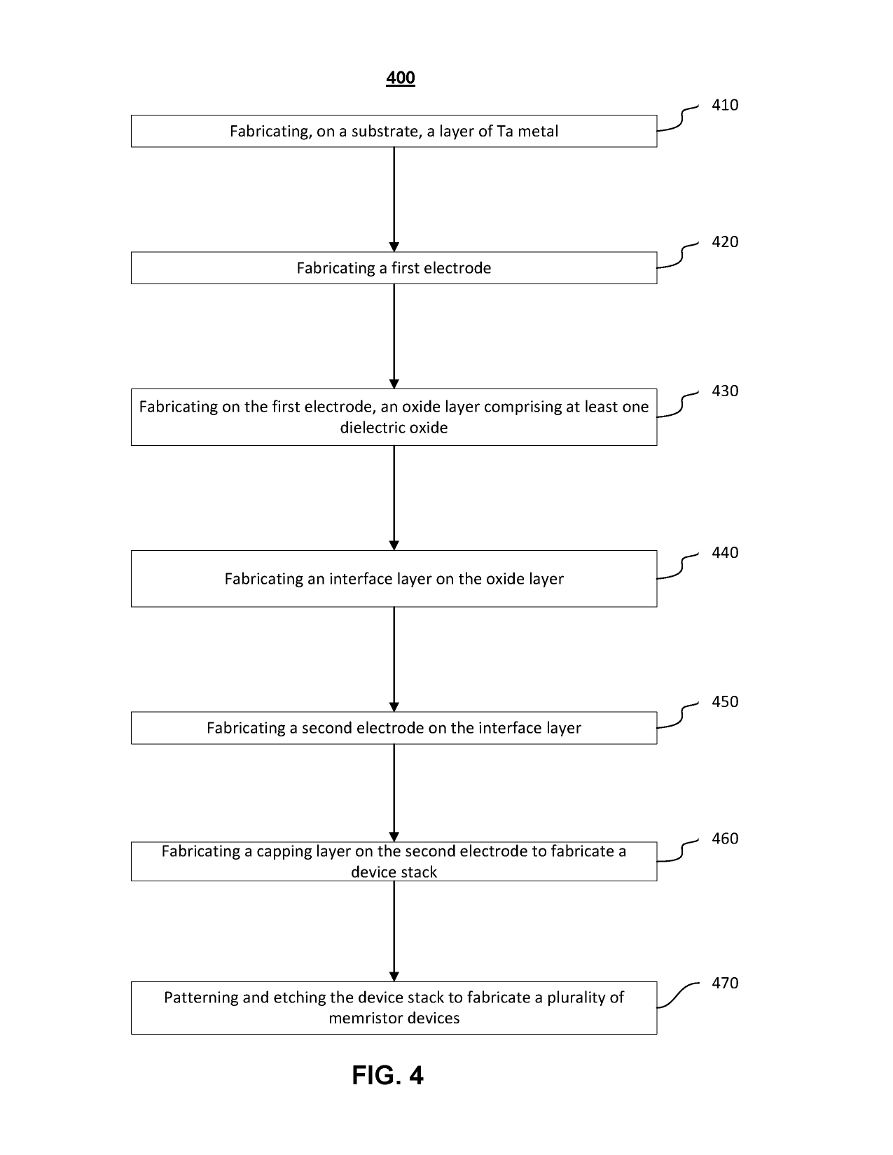

FIGS. 4, 5, and 6 are flow diagrams illustrating example processes 400, 500, and 600 for fabricating memristor devices in accordance with some embodiments of the present disclosure.

Referring to FIG. 4, process 400 may start at 410, where a layer of tantalum metal may be fabricated on a substrate. The layer of tantalum metal may be fabricated, for example, using physical vapor deposition (PVD),chemical vapor deposition (CVD), sputtering, etc. The layer of tantalum metal may be the layer 115 as described in connection with FIG. 1H.

At 420, a first electrode may be fabricated on the substrate and/or the layer of tantalum metal. For example, a layer of a suitable electrically conductive material may be deposited utilizing atomic layer deposition (ALD), CVD, metal-organic chemical vapor deposition (MOCVD), PVD, molecular beam epitaxy (MBE) deposition, etc. The electrically conductive material may include, for example, Pt, Pd, Ir, W, Mo, Ru, etc. The first electrode may be the first electrode 120 as described in connection with FIG. 1B and/or FIG. 1H.

At 430, an oxide layer may be fabricated on the first electrode. The oxide layer may include at least one dielectric oxide. The dielectric oxide may be a base oxide in stoichiometry or close to stoichiometry, such as Ta₂O₅, HfO₂, SiO₂, etc. The oxide layer may be fabricated, for example, by depositing the dielectric oxide using ALD, CVD, PVD, Plasma-Enhanced Chemical Vapor Deposition (PECVD), and/or any other suitable deposition technique. The oxide layer may be the oxide layer 130 as described in connection with FIG. 1C and/or FIG. 1H.

At 440, an interface layer may be fabricated on the oxide layer. The interface layer may include a discontinuous layer of a dielectric material. The interface layer may include a dielectric material that is more chemically stable than the dielectric oxide in the oxide layer and the electrode materials in the first electrode and/or the second electrode, such as Al₂O₃, Y₂O₃, MgO, etc. Fabricating the interface layer may involve depositing a discontinuous layer of the dielectric material, utilizing an ALD technique, a physical vapor deposition (PVD) technique, reactive sputtering technique, and/or any other suitable deposition technique. The interface layer may be and/or include the interface layer 140 as described in connection with FIGS. 1C and 1H above.

At 450, a second electrode may be fabricated on the interface layer and the oxide layer. Fabricating the second electrode may involve depositing one or more metallic materials that may provide metal ions for drift switching of the memristor device to be fabricated. For example, fabricating the second electrode may involve depositing Cu, Ag using deposition processes such as PVD, electroplating, sputtering, etc. As the interface layer includes a discontinuous layer of the dielectric material, at least a portion of the second electrode may be deposited on the oxide layer through the interface layer (e.g., through the pinholes in the discontinuous layer of the dielectric material). The second electrode may be the second electrode 150 as described in connection with FIGS. 1D and 1H.

At 460, a capping layer may be fabricated on the second electrode to fabricate a device stack. Fabricating the capping layer may involve depositing Ta, TaN, W, WN, etc. using deposition techniques such as sputtering, CVD, ALD, etc. The capping layer may be the capping layer 160 as described in connection with FIGS. 1E and 1H above. The device stack may be the device stack 100 of FIG. 1E and/or device stack 170 of FIG. 1H.

At 470, the device stack may be patterned and etched to fabricate a plurality of memristor devices, such as the memristor devices 100a, 100b, . . ., 100c of FIG. 1F and/or memristor devices 170a, 170b, . . ., 170c of FIG. 1I.

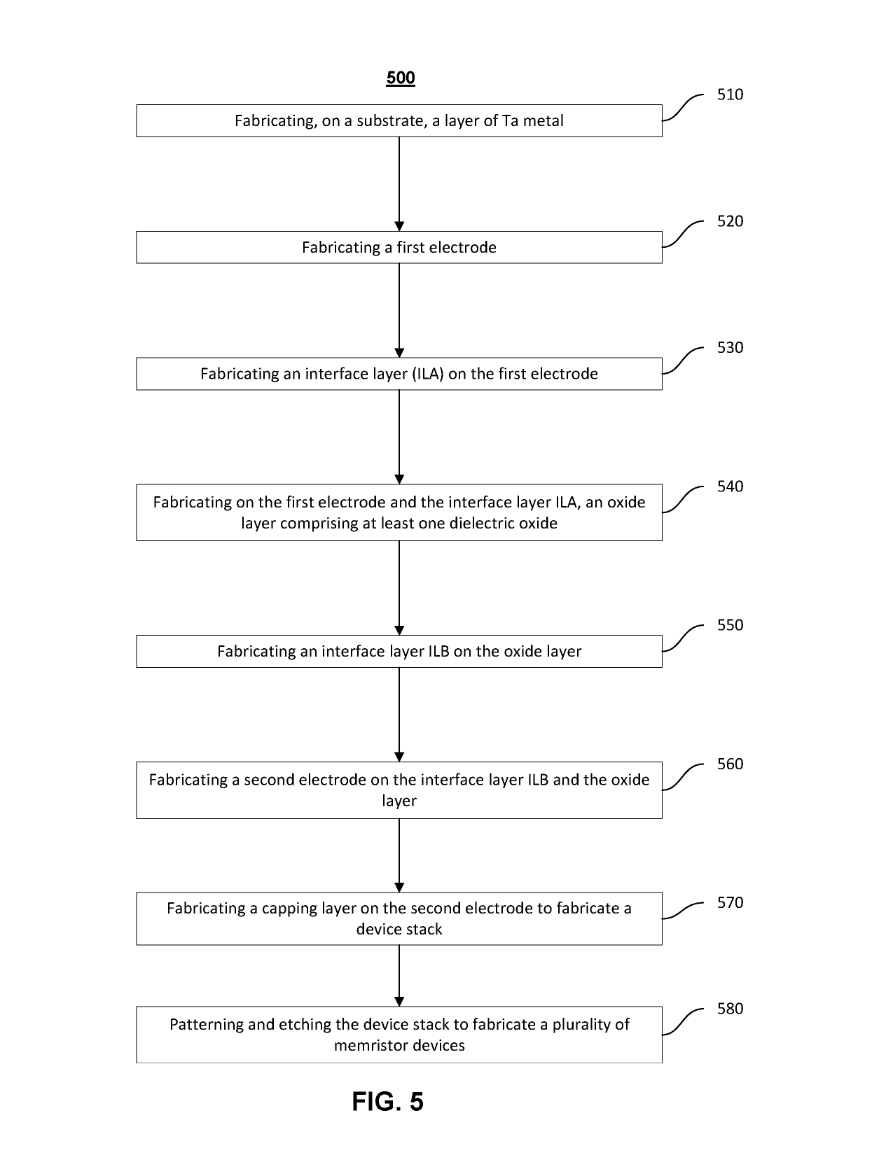

Referring to FIG. 5, process 500 may start at 510, where a layer of tantalum metal may be fabricated on a substrate. Blocks 510 and 410 may be performed in substantially the same manner.

At 520, a first electrode may be fabricated on the substrate and/or the layer of tantalum metal. Blocks 520 and 420 may be performed in substantially the same manner.

At 530, an interface layer ILA may be fabricated on the first electrode. Fabricating the interface layer ILA may involve depositing a discontinuous layer of a dielectric material that is more chemically stable than the dielectric oxide in the oxide layer and the electrode materials in the first electrode and/or the second electrode, such as Al₂O₃, Y₂O₃, MgO, etc. In some embodiments, the dielectric material may be deposited on the first electrode to a suitable thickness to form a discontinuous film of the dielectric material. The dielectric material may be deposited utilizing an ALD technique, a PVD technique, reactive sputtering, and/or any other suitable deposition technique. The interface layer ILA may be the interface layer 230 as described in connection with FIG. 2A.

At 540, an oxide layer may be fabricated on the first electrode and the interface layer ILA. The oxide layer may include at least one dielectric oxide. The dielectric oxide may be a base oxide in stoichiometry or close to stoichiometry, such as Ta₂O₅, HfO₂, SiO₂, etc. The oxide layer may be fabricated, for example, by depositing the dielectric oxide using ALD, CVD, PECVD, and/or any other suitable deposition technique. Since the interface layer ILA includes a discontinuous layer of the second dielectric material, at least a portion of the dielectric oxide is deposited on the first electrode through the interface layer ILA and at least a portion of the oxide layer is in direct contact with the first electrode. The oxide layer may be the oxide layer 240 as described in connection with FIG. 2B.

At 550, an interface layer ILB may be fabricated on the oxide layer. The interface layer ILB may be the interface layer 250 as described in connection with FIG. 2C. Blocks 550 and 440 may be performed in substantially the same manner.

At 560, a second electrode may be fabricated on the interface layer ILB and the oxide layer. The second electrode may be the second electrode 260 of FIG. 2D. Blocks 560 and 450 may be performed in substantially the same manner

At 570, a capping layer may be fabricated on the second electrode to form a device stack. The capping layer may be the capping layer 270 as described in connection with FIG. 2E above. Blocks 570 and 460 may be performed in substantially the same manner. The device stack may be the device stack 200 as described in connection with FIG. 2E.

At 580, the device stack may be patterned and etched to fabricate a plurality of memristor devices (e.g., memristor devices 200a, 200b, . . ., 200c, as shown in FIG. 2F).

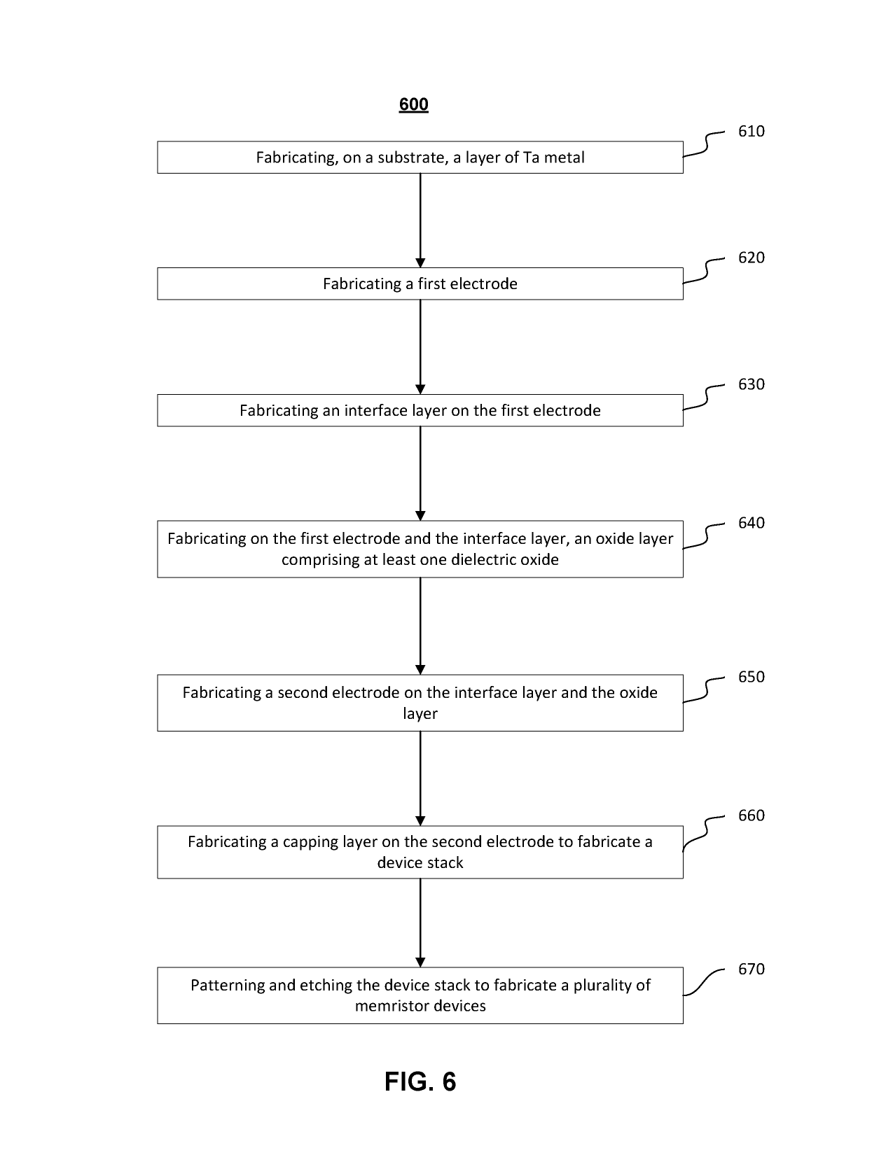

Referring to FIG. 6, process 600 may start at 610, where a layer of tantalum metal may be fabricated on a substrate. Blocks 610 and 410 may be performed in substantially the same manner.

At 620, a first electrode may be fabricated on the substrate and/or the layer of tantalum metal. Blocks 620 and 420 may be performed in substantially the same manner.

At 630, an interface layer may be fabricated on the first electrode. Fabricating the interface layer may involve depositing a discontinuous layer of a dielectric material that is more chemically stable than the dielectric oxide in the oxide layer and the electrode materials in the first electrode and/or the second electrode, such as Al₂O₃, Y₂O₃, MgO, etc. In some embodiments, the dielectric material may be deposited on the first electrode to a suitable thickness to form a discontinuous film of the dielectric material. The dielectric material may be deposited utilizing an ALD technique, a PVD technique, reactive sputtering, and/or any other suitable deposition technique. The interface layer ILA may be the interface layer 230 as described in connection with FIG. 3A.

At 640, an oxide layer may be fabricated on the first electrode and the interface layer ILA. The oxide layer may include at least one dielectric oxide. The dielectric oxide may be a base oxide in stoichiometry or close to stoichiometry, such as Ta₂O₅, HfO₂, SiO₂, etc. The oxide layer may be fabricated, for example, by depositing the dielectric oxide using ALD, CVD, PECVD, and/or any other suitable deposition technique. Since the interface layer includes a discontinuous layer of the second dielectric material, at least a portion of the dielectric oxide is deposited on the first electrode through the interface layer ILA and at least a portion of the oxide layer is in direct contact with the first electrode. The oxide layer may be the oxide layer 240 as described in connection with FIG. 2B.

At 650, a second electrode may be fabricated on the oxide layer. Fabricating the second electrode may involve depositing one or more metallic materials on the oxide layer. The metallic materials may provide metal ions for drift switching of the memristor device to be fabricated. For example, fabricating the second electrode may involve depositing Cu, Ag using deposition processes such as PVD, electroplating, sputtering, etc. The second electrode may be the second electrode 350 of FIG. 3A.

At 660, a capping layer may be fabricated on the second electrode to form a device stack. The capping layer may be the capping layer 360 as described in connection with FIG. 3B above. Blocks 660 and 460 may be performed in substantially the same manner. The device stack may be the device stack 300 as described in connection with FIG. 3B.

At 670, the device stack may be patterned and etched to fabricate a plurality of memristor devices (e.g., memristor devices 300a, 300b, . . ., 300c, as shown in FIG. 3C).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words "example" or "exemplary" are used herein to mean serving as an example, instance, or illustration. Any aspect or design described herein as "example" or "exemplary" is not necessarily to be construed as preferred or advantageous over other aspects or designs. Rather, use of the words "example" or "exemplary" is intended to present concepts in a concrete fashion. As used in this application, the term "or" is intended to mean an inclusive "or" rather than an exclusive "or". That is, unless specified otherwise, or clear from context, "X includes A or B" is intended to mean any of the natural inclusive permutations. That is, if X includes A; X includes B; or X includes both A and B, then "X includes A or B" is satisfied under any of the foregoing instances. In addition, the articles "a" and "an" as used in this application and the appended claims should generally be construed to mean "one or more" unless specified otherwise or clear from context to be directed to a singular form. Reference throughout this specification to "an implementation" or "one implementation" means that a particular feature, structure, or characteristic described in connection with the implementation is included in at least one implementation. Thus, the appearances of the phrase "an implementation" or "one implementation" in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

1. A semiconductor device, comprising:
a memristor device, comprising:
a first electrode;
an oxide layer fabricated on the first electrode, wherein the oxide layer comprises at least one dielectric oxide;
a second electrode fabricated on the oxide layer; and
a first interface layer fabricated between the oxide layer and the second electrode, wherein the first interface layer comprises a layer of a first dielectric material.

2. The semiconductor device of claim 1, wherein the first electrode comprises at least one of platinum (Pt), palladium (Pd), iridium (Ir), tungsten (W), molybdenum (Mo), or ruthenium (Ru).

3. The semiconductor device of claim 2, wherein the dielectric oxide comprises at least one of silicon dioxide (SiO₂), hafnium dioxide (HfO₂), or tantalum pentoxide (Ta₂O₅).

4. The semiconductor device of claim 3, wherein the first dielectric material comprises at least one of Al₂O_{3,} Y₂O_{3,} or MgO.

5. The semiconductor device of claim 4, wherein the second electrode comprises at least one of Cu or Ag.

6. The semiconductor device of claim 5, wherein the first interface layer comprises a discontinuous layer of the first dielectric material, and wherein at least a portion of the second electrode is deposited on the oxide layer through the discontinuous layer of the first dielectric material.

7. The semiconductor device of claim 1, further comprising a capping layer fabricated on the second electrode, wherein the capping layer comprises a metal.

8. The semiconductor device of claim 1, further comprising a layer of tantalum deposited between the first electrode and a substrate.

9. The semiconductor device of claim 1, wherein the memristor device comprises a second interface layer fabricated between the first electrode and the oxide layer, wherein the second interface layer comprises a second dielectric material.

10. The semiconductor device of claim 9, wherein the second dielectric material comprises at least one of Al₂O_{3,} Y₂O_{3,} or MgO, and wherein the second interface layer comprises a discontinuous layer of the second dielectric material, and wherein at least a portion of the oxide layer comprising the dielectric oxide is deposited on the first electrode through the second interface layer.

11. A method for fabricating a memristor device, comprising:
fabricating, on a first electrode, an oxide layer comprising at least one dielectric oxide;
fabricating, on the oxide layer, an interface layer comprising a first dielectric material; and
fabricating a second electrode on the interface layer and the oxide layer.

12. The method of claim 11, wherein the first electrode comprises at least one of platinum (Pt), palladium (Pd), iridium (Ir), tungsten (W), molybdenum (Mo), or ruthenium (Ru).

13. The method of claim 12, wherein the dielectric oxide comprises at least one of silicon dioxide (SiO₂), hafnium dioxide (HfO₂), or tantalum pentoxide (Ta₂O₅).

14. The method of claim 13, wherein the first dielectric material comprises at least one of Al₂O_{3,} Y₂O_{3,} or MgO.

15. The method of claim 14, wherein the second electrode comprises a metallic material for providing metal ions during drift switching of the memristor device, wherein the metallic material comprises at least one copper (Cu) or silver (Ag).

16. The method of claim 15, wherein the first interface layer comprises a discontinuous layer of the first dielectric material, and wherein fabricating the second electrode comprises depositing at least a portion of the metallic material on the oxide layer through the discontinuous layer of the first dielectric material.

17. The method of claim 11, further comprising fabricating a capping layer on the second electrode, wherein the capping layer comprises at least one of a metal or a metal nitride.

18. The method of claim 11, further comprising depositing a layer of tantalum metal on a substrate, wherein the first electrode is fabricated on the layer of tantalum.

19. The method of claim 11, further comprising fabricating, on the first electrode a second interface layer comprising a second dielectric material, wherein the oxide layer is fabricated on the second interface layer.

20. The method of claim 19, wherein the second dielectric material comprises at least one of Al₂O_{3,} Y₂O_{3,} or MgO, and wherein the second interface layer comprises a discontinuous layer of the second dielectric material, and wherein at least a portion of the oxide layer comprising the dielectric oxide is deposited on the first electrode through the second interface layer.
